(19) United States
(12) Patent Application Publication
(10) Pub. No.: US 2023/0005714 A1
(43) Pub. Date: Jan. 5, 2023

(54) GAS NOZZLE

(71) Applicant: CoorsTek KK, Tokyo (JP)

(72) Inventors: Kana KAWAKAMI, Hadano-shi (JP); Manami SUGIYAMA, Hadano-shi (JP)

(73) Assignee: CoorsTek KK, Tokyo (JP)

(21) Appl. No.: 17/847,601

(22) Filed: Jun. 23, 2022

(30) Foreign Application Priority Data
Jul. 5, 2021 (JP) 2021-111228
May 25, 2022 (JP) 2022-086969

(51) Int. Cl. H01J 37/32; B05B 1/00; B05B 1/14

(52) U.S. Cl. CPC H01J 37/3244; B05B 1/005; B05B 1/14

(57) ABSTRACT

A gas nozzle having a fired surface excellent in particle reduction effect is provided. The gas nozzle 1 is a columnar gas nozzle made of sintered ceramics, provided with at least one through-hole 2 through which gas flows. The entire inner surface 2a of the through-hole 2 and the end face 1A on which outlet 2b of the through-hole 2 is provided are both fired surfaces. The inner surface 2a of the through-hole 2 has a first region A in the vicinity of the outlet 2b and a second region B which is located at a further position than the first region A. The average crystal grain size in the first region A is formed to be smaller than the average crystal grain size in the second region B.

### TECHNICAL FIELD

This invention relates to gas nozzles, for example, a gas nozzle made of sintered ceramics that jets corrosive gases, which is to be used in apparatus using plasma processes, such as semiconductor manufacturing apparatus.

### BACKGROUND ART

One of the corrosion-resistant components for plasma process apparatus is a gas nozzle, which is installed to introduce etching gas into the processing apparatus and exposed to a plasma atmosphere.

The overall shape of a general gas nozzle is formed into a so-called columnar shape. That is, the overall shape of the gas nozzle has a pair of end faces formed in the shape of a circle, ellipse, or polygon, and a side portion having a predetermined length in an approximately vertical direction with formed between said pair of end faces.

The gas nozzle has a plurality of through-holes along the axis of the columnar body where gases such as etching gas, for example, pass through. The material of the gas nozzle is typically sintered yttria or sintered alumina, which has excellent corrosion resistance.

One of the technical problems of gas nozzles made of sintered ceramics is the generation of particles from the gas nozzles, and several measures have been taken to reduce this problem. As one of the solutions, a technology focusing on the surface condition of the inner wall of the gas nozzle is disclosed in PTL 1.

The gas nozzle disclosed in PTL 1 is described based on FIGS. 2 and 3. FIG. 2 is a perspective view of a schematic diagram of the gas nozzle, and FIG. 3 is an I-I cross-sectional view of FIG. 2.

The gas nozzle 10 shown in PTL 1, similar to a typical gas nozzle, is composed of a columnar body made of sintered ceramic having through-holes 13 through which gas flows, and outflow ports 14 for the gas at the through-holes 13 are formed on one end face 11 of the main body.

Further, as shown in FIG. 3, an inside wall 13a of the through-hole 13 in the gas nozzle 10 has two regions: a first region A located in the vicinity of the outflow port 14 and a second region B located in an inner portion of the main body, compared to region A. The first region A and the second region B have untreated faces of the ceramic sintered body. The average crystal grain size in the first region A is formed to be larger than the average crystal grain size in the second region B.

### CITATION LIST

### Patent Literature

PTL 1: WO2014-119177

### SUMMARY OF INVENTION

### Technical Problem

PTL 1 recites “When the average crystal grain size in the fired surface of the ceramic sintered body is large, a ratio of a region in the fired surface of the crystal grain boundary which is likely to be corroded by plasma is reduced. For this reason, when the fired surface is exposed to the plasma-converted gas, particles are unlikely to fall off. Therefore, since the first region is located in the vicinity of the outlet, it is possible to satisfactorily reduce generation of particles in the first region that is likely to be exposed to the plasma-converted gas.”

Accordingly, PTL 1 shows that when the average crystal grain size in the vicinity of the outlet 14 of the gas nozzle 10 is large, the generation of particles can be reduced.

PTL 1 recites “Additionally, when the average crystal grain size in the fired surface of the ceramic sintered body is small, the filling rate of crystal grain in the fired surface is increased. For this reason, mechanical strength of the fired surface is increased. Therefore, in the second region that is unlikely to be exposed to the plasma-converted gas compared to the first region because of being located further inward of the main body, damage of the main body due to mechanical stress or thermal stress can be suppressed by increasing the mechanical strength while reducing influence by the plasma-converted gas.”

However, when the inventors verified the gas nozzle described in PTL 1, the particle reduction effect was small and its performance was not always satisfactory.

As a result of the intensive studies of the inventors, they found that it is more effective to reduce particle generation if the average crystal grain size of the inner wall of the outlet side of the gas nozzle is smaller than the average crystal grain size of the inner wall of the back side, and this led to the completion of the present invention.

The present invention was made in view of the above situation, and it is an object to provide a gas nozzle with a fired surface that is more effective in reducing particles.

### Solution to Problem

The gas nozzle is a columnar gas nozzle made of sintered ceramics having at least one through-hole through which gas flows, wherein both the entire inner surface of the through-hole and the end face where the outlet of the through-hole is provided are fired surfaces, and the inner surface of the through-hole has a first region A in the vicinity of the outlet and a second region B located at a deeper position than the first region A. The average crystal grain size in the first region A is smaller than the average crystal grain size in the second region B.

In the gas nozzle of the present invention, the above configuration can effectively suppress particle generation in gas nozzles with a fired surface.

In addition, in the gas nozzle of the present invention, specifically, the first region A is at a distance of 0.5 mm from the end face of the outlet, and the second region B is at a deeper position than the first region A and within 3 mm from the end face of the outlet, and the average crystal grain size in the second region B is preferably 1.2 times or less than the average grain size in the first region A.

### Advantageous Effects of Invention

According to the present invention, a gas nozzle with a fired surface that is more effective in reducing particles can be obtained.

### BRIEF DESCRIPTION OF DRAWINGS

FIG. 1 is a schematic cross-sectional view illustrating a first region A and a second region B of a gas nozzle according to the present invention;

FIG. 2 is a schematic perspective view of a conventional gas nozzle; and

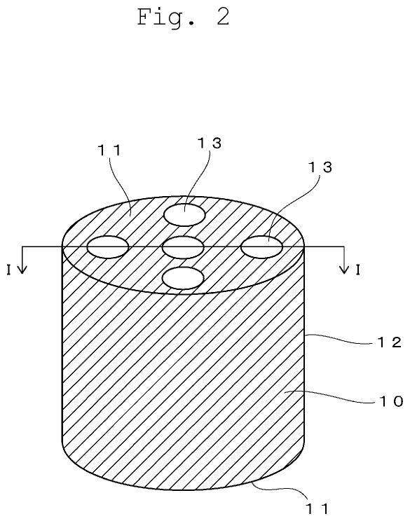

FIG. 3 is an I-I cross-sectional view in FIG. 2.

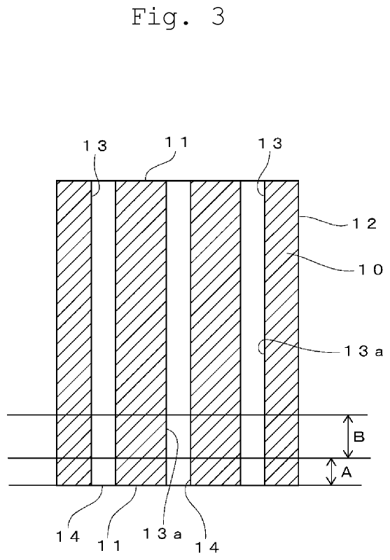

### DESCRIPTION OF EMBODIMENTS

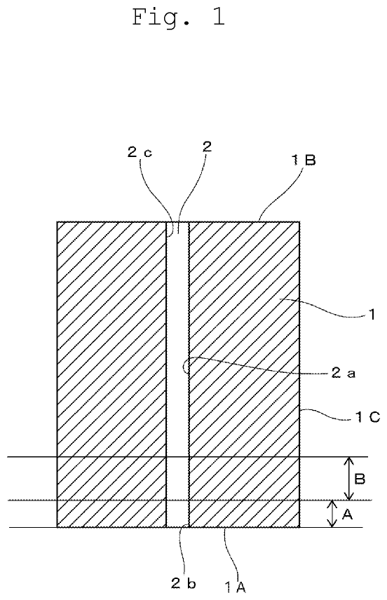

An embodiment of a gas nozzle according to the present invention will be described based on FIG. 1.

A gas nozzle 1 is a columnar gas nozzle made of sintered ceramics, provided with at least one through-hole 2 through which gas flows, similar to the conventional gas nozzle 10.

Specifically, the gas nozzle has end faces 1A and 1B, which are approximately planar and opposing to each other, and at least one through-hole 2 penetrating these end faces 1A and 1B. The through-hole 2 has openings at the end face 1A to form an outlet 2b and at the end face 1B to form an inlet 2c.

The gas nozzle 1 is formed in a columnar shape having the end faces 1A and 1B that have either a circular, elliptical, or polygonal shape and a side face 1C having a predetermined length extending perpendicularly or obliquely to the end faces 1A and 1B.

The gas nozzle 1 can be designed by appropriately selecting a known shape and size as a gas nozzle for jetting corrosive gas used in plasma process apparatus.

The gas nozzle 1 is made of ceramics having excellent corrosion resistance, more preferably one containing yttria as its main component.

Further, it is preferable to use sintered yttria to which tantalum oxide is added by 0.5 to 5 wt %. In yttria added with tantalum oxide properly, the anomalous growth of crystal grains is inhibited when fired, and the difference in the average grain size between the first region A and the second region B can be made in an appropriate predetermined range.

The face of the gas nozzle 1 coming into contact with plasma and corrosive gas is formed as a fired surface. The end face 1A and the entire inner surface 2a of the through-hole 2 correspond to the face.

That is, in the nozzle 1, at least, both the entire inner surface 2a of the through-hole 2 and the end face 1a, where the outlet 2b of the through-hole 2 is provided, are formed as fired surface.

Faces other than the entire inner surface 2a of the through-hole 2 and the end face 1a, where the outlet 2b of the through-hole 2 is provided may be processed or fired surfaces. Moreover, the whole surface of the nozzle 1 may be fired surface.

The fired surface is the surface without polishing, grinding, or other processing, and without covering or coating treatment after firing of ceramics to the fired surface, but chemical treatments for cleaning control may be appropriately performed.

The side surface 1C of the gas nozzle 1 may be left fired surfaced. Or the fired surface thereof may be subjected to processing such as polishing or grinding, and/or covering or coating treatment may be performed thereon.

As escribed above, both the entire inner surface 2a of the through-hole 2 and the end face 1a, where the outlet 2b of the through-hole 2 is provided of the gas nozzle 1 are left fired-surfaced and are kept in a state without being subjected to processing such as polishing or grinding. Accordingly, no crushing layer due to processing exists.

Consequently, even when the fired surface is damaged by plasma, the generation of particularly large particles caused by the peeling of the crushing layer is inhibited.

Further, the inner surface 2a of the through-hole 2 has a first region A in the vicinity of the outlet 2b and a second region B located at a deeper position than the first region A. The average crystal grain size in the first region A is formed to be smaller than the average crystal grain size in the second region B.

As shown in FIG. 1, the first region A and the second region B are formed continuously from the outlet 2b to the depth side of the gas nozzle 1.

The particle generation due to peeling off of the crystal grains is suppressed when the average crystal grain size in the first region A is formed to be smaller than the average crystal grain size in the second region B.

Though the reason has not been clarified clearly at present, it can be estimated that the small average crystal grain size in region A which is more prone to be strongly exposed to plasma increases the strength of the surface, and thus, the surface withstands the physical impacts of radicals when exposed to the plasma, and consequently, the generation of particles is suppressed.

In the case of the gas nozzle of the apparatus, which supplies a halogen-based corrosive gas as raw material gas into a reaction chamber and turns it into a plasmanized etching gas to perform microfabrication on an object, it can be thought that in the region B of the gas nozzle where, for example, halogenated corrosive gases (e.g., fluorinated gases) come in contact in a larger area ratio rather than plasma the increase in the average grain size reduces the number of grain boundaries and makes the grain boundaries more resistant to corrosion by halogenated corrosive gases, and as a result, the generation of particles by corrosion is inhibited. Considering the balance between effects on sintered ceramics and grain size that each of plasma and halogenated corrosive gas (e.g., fluorine gas) has, it is considered that the size relationship of the average crystal grain size as in the present invention is suitable.

As concretely shown in one embodiment of the first region A and the second region B, the distance from the outlet in the depth direction in the first region A is within 0.5 mm, and the distance from the outlet in the depth direction in the second region B which is further to depth side of the first region A is within 3 mm. The average crystal grain size in the second region B is 1.2 times or less than that in the first region A. The average crystal grain size in the first region A is 3 μm to 3.5 μm and that of the second region B is 3.4 μm to 4 μm.

The average grain size is obtained by analyzing the taken pictures with an image analysis tool (Product name: Mac-View), which pictures are taken by observing and shooting the surfaces of the first region A and the second region B with a scanning electron microscope (SEM).

The reason why the first region A is at a distance within 0.5 mm from the outlet in the depth direction is that, when fired, this region is likely to be affected by heating by conduction, and the grain size is apt to become larger; as a result, the difference in grain size between ones in the first region A and the second region B becomes clear.

Further, the reason why the second region B is at a distance within 3 mm from the outlet further in the depth direction from the first region A is that firing progresses in this region at an approximately constant temperature due to heating by conduction; as a result, the grain size becomes a nearly constant distribution. That is, the grain size is stable in this region and the region further in the depth direction, and these regions are sufficient to identify as the region where the advantageous effects of the present invention are obtained.

In addition, the effects of the present invention are further exerted by setting the average crystal grain size in the second region B to be 1.2 times or less than that in the first region A.

When the average crystal grain size in the second region B exceeds 1.2 times or more than that in the first region A, the stress difference between crystals becomes too much and it may cause peeling of at the boundary, at the inner wall, of the region A and the region B.

The gas nozzle 1 is manufactured by a typical manufacturing method.

One example is as follows:

First, a slurry is prepared by wet-mixing in a ball mill after adding water and an organic binder to a ceramics powder. Then, ceramic granulated powder are prepared by granulating the slurry by spray drying.
The ceramic granulated powder is formed into a predetermined shape using a molding method such as a die press molding method or cold isostatic pressing (CIP) molding method to obtain a cylindrical, for example, molding.
Next, after boring through-holes into the molding, the molding is fired at a temperature of 1400° C. or higher and 2000° C. or lower in air ambient atmosphere or oxygen atmosphere to obtain a gas nozzle according to the present invention. Because the gas nozzle is not processed after firing, the entire region of the inner surface 2a of the through-holes 2, the end face 1A where the outlet 2b of the through-hole 2, and other surfaces have fired surfaces.

When the moldings are fired in a firing furnace after preparing moldings having a predetermined shape, the moldings are preferably arranged to quicken heating at the outlet 2b of the gas nozzle 1.

Specifically, when the molding is mounted on a mounting table, a portion to be the outlet 2b of the gas nozzle 1 of the molding is mounted to come into contact with the mounting table; that is, a portion to be the inlet 2c of the gas nozzle 1 of the molding is mounted to face upward.

With this, at the time of firing the molding, the molding is heated inward from the upper portion, the inlet 2c, and the heat escapes from the outlet 2b side to the mounting table. As a result, the second region B, located inside the molding, is largely heated in comparison to the first region A, located in the vicinity of the outlet 2b.

In the case where the gas nozzle is formed of, for example, yttria sintered body, yttrium-aluminum-garnet sintered body, spinel sintered body, or high-purity alumina sintered body, liquid-phase sintering occurs when molding is fired.

With this, the grain size in the second region B, to which larger heat is subjected, is likely to grow larger than that in the first region A. As a result, the average crystal grain size in the first region A can be made smaller than that in the second region B.

It is preferable to provide the molding so that the the outlet 2b of the gas nozzle 1 is mounted on the mounting table in the firing furnace. With this method, it is relatively easy to achieve the average grain size as that of the aspect in the present invention.

The entire inner surface of the through-hole and the end faces in which the outlet of the through-hole is provided are not machined such as grinding or polishing.

This is to prevent the formation of the crushing layer by machining and to inhibit the generation of particularly large particles caused by the peeling of the crushing layer, even when the fired surface is damaged by plasma.

As described above, the desired gas nozzle can be made. In particular, when the moldings are fired in a firing furnace after preparing moldings having a predetermined shape, the moldings are preferably arranged to quicken heating at the outlet 2b of the gas nozzle 1.

For example, by mounting a portion to be the outlet 2b of the gas nozzle 1 of the molding to come into contact with the mounting table, it is relatively easy to achieve the average grain size as that of the aspect in the present invention.

### EXAMPLES

The invention will be specifically described below based on examples, but the invention is not limited by the examples shown below.

### Example 1

### Manufacturing Condition—Preparation of Firing Body

Yttria powder with a purity of 99.9% or higher, pure water, and as a sintering aid, silica, tantalum oxide, and other commercially available organic binders were each weighed and wet mixed in a ball mill to form a slurry.

The slurry is then granulated by spray drying. The particle size of the granulated powder was in the range of 17 μm to 40 μm.

Granulated yttria powder was formed into a columnar molding having one through-hole with a diameter of 1.5 mm at the center of the end face of a gas nozzle by cold isostatic pressing (CIP) molding method.

The molding was heated at 1100° C. or higher to degrease and decompose the organic binder in an air atmosphere and fired at 1800° C. or higher in a hydrogen atmosphere. Gas nozzles for evaluation were fabricated through the above process.

### Example 1

In Example 1, the outlet of the gas nozzle is disposed to come into contact with the mounting table. Specifically, the end face 1A of the gas nozzle shown in FIG. 1 is placed on the bottom side (to the mounting table) and the end face 1B is placed on the top side. The gas nozzles for evaluation were then prepared under the common manufacturing conditions described above.

The end face 1A of the gas nozzle was placed on the mounting table using a jig that only made contact with the flange of the end face 1 to avoid direct contact with the mounting table.

That is, a jig (annular) made of the same material (yttria) and condition (with the surface as fired) as the nozzle was prepared, and the flange portion of the end face 1A was placed on the mounting table using the jig to the end face 1A not to come into contact directly with the mounting table. In this case, yttria powder was spread between the flange portion of end face 1A and the jig to reduce the contact region. The shape of the jig is not strictly limited, as long as it can support the flange portion of the end face 1A with a very narrow contact region.

### Comparative Example 1

As for Comparative Example, the outlet of the gas nozzle was placed toward the opposite direction to the mounting table in the firing furnace. In other words, the gas nozzle was placed upside down, compared to Example 1, with the end face 1A of the gas nozzle on the upper side and the end face 1B on the lower side. The gas nozzles for evaluation were then prepared under the similar manufacturing conditions to Example 1.

### Evaluation 1: The Average Crystal Grain Size.

The average crystal grain size of the inner surface of the through-hole was measured from the outlet of the gas nozzle (the end face) to the depth direction for Example 1 and Comparative Example 1. Measurement was carried out at every 0.5 mm from the outlet of the gas nozzle as the zero position. The measured values at two positions at zero mm and 0.5 mm in the first region A and the measured values at three positions at 1.0 mm, 1.5 mm, and 2.0 mm in the second region B were respectively averaged.

For the measurement, images of the inner surface are taken using a non-contacting optical measurement tool and the number of particles and the average crystal grain size are obtained by image analysis.

### Evaluation 2: Generation of Particles.

For Example 1 and Comparative Example 2, corrosion test for 12 hours is carried out with plasma of carbon tetrachloride CF₄ in an inductively coupled plasma (ICP) etching chamber. Then, the generation of particles was measured using a publically known aerial particle counter.

In the evaluation 1 and 2, in Example 1, the average crystal grain size in the first region A is 3.3 μm and that in the second region B is 3.9 μm, and the ratio of the average grain size of the second region B to that of the first region A is 1.18, and the number of the generated particles is 1000 pts.

In the evaluation 1 and 2, in Comparative Example 1, the average crystal grain size in the first region A is 5.8 μm and that in the second region B is 5.2 μm, and the ratio of the average grain size of the second region B to that of the first region A is 0.9, and the number of the generated particles is 2000 pts.

As described above, when the average grain size of the first region A is smaller than the average grain size of the second region B, the amount of particles generated is smaller than that when the average grain size of the first region A is larger than the average grain size of the second region B. The ratio of the average grain size of the second region B to that of the first region A was 1.18, i.e. 1.2 times or less.

### Example 2

As seen from the results of Example 1, it is preferable that the distance of the first region A is within 0.5 mm from the end face of the outlet of the gas nozzle toward the depth direction and the distance in the second region B is within 3.0 mm from the end face of the outlet of the gas nozzle further toward the depth direction from the first region A. As for the distance from the end face of the outlet of the region A to the depth direction, the distance can be adjusted by firing temperature, for example. Then, in Example 2, by adjusting the firing temperature, the gas nozzle was formed so that the distance from the end face of the outlet of the first region A was made to be more than 0.5 mm but within 1 mm.

The firing temperature in actual manufacturing is determined by taking into consideration the density of the entire gas nozzle, the uniformity of the particle size distribution, and the occurrence of cracks during firing. However, only the firing temperature was intentionally varied as a verification of the effect of the invention.

The distance from the end face of the outlet of the second region B is specified to identify the first region A and is dependent on the distance from the end face of the outlet of the first region A. Therefore, the independent control of only the distance from the end face of the outlet of the second region B is not implemented in this invention.

In Example 2, as described above, the firing temperature was 1700° C., which is lower than that in Example 1 where the firing temperature was 1800° C., such that the distance from the end face of the outlet in the first region A was more than 0.5 mm but within 1 mm.

The gas nozzles were manufactured and evaluated in the same manner as in Example 1 except the firing temperature condition.

### Evaluation 1: Average Crystal Grain Size

As for Example 2, the average crystal grain sizes of the inner wall surface of the through-hole were measured from the outlet, the end face, of the gas nozzle toward the depth direction. Measuring positions were every 0.5 mm from the outlet of the gas nozzle being as zero. The values measured at three points at 0 mm, 0.5 mm, and 1.0 mm for the first region A, and at two points at 1.5 mm and 2.0 mm for the second region B were averaged. For the measurement, pictures at the positions on the inner wall were shot and taken by a scanning electron microscope and the number of the particles and the average crystal grain size were obtained by image analysis.

### Evaluation 2: Generation of Particles

As for Example 2, a corrosion test for twelve hours with irradiating plasma of CF4 in a chamber of a publicly known ICP etching apparatus was conducted. Then, the number of generated particles was measured with a publicly known aerial particle counter.

In Evaluation 1, for the case of Example 2, the average crystal grain size in the first region A is 3.0 μm and that in the second region B is 3.4 μm, and the ratio of the average crystal grain size in the second region B to that in the first region A is 1.14.

In the Evaluation 2, the number of generated particles was 1500 pts. The area of the first region A where the average crystal grain size is small relatively increases than that in Example 1 due to the increase in distance from the end face of the outlet of the first region A exceeding 0.5 mm to the depth direction. Because of this, the area of the first region A, where the grain boundaries are less resistant to halogen-based corrosive gas, becomes larger than the area of the second region B. It is speculated that accordingly, the number of generated particles increases in comparison with the case of Example 1.

### Example 3

The effect on the number of generated particles due to the ratio of the average grain size of the second region B to that of the first region A can be adjusted by selecting jigs having different height, which means different distances from the end face 1A to the surface of the mounting table.

Then, in Example 3, the effects on the number of generated particles were verified by changing only the jig height, which is the distance from the end face 1A to the surface of the mounting table, among the conditions in Example 1.

The jig used in Example 1 was 30 mm in height, while the jig having a height of 10 mm was used in Example 3. Gas nozzles were manufactured under similar conditions to Example 1 except for the jig height, and Evaluations 1 and 2 were conducted on the nozzles similarly to Example 1.

The gas nozzle manufactured in Example 3, similar to Example 1, has a distance of 0.5 mm from the end face of the outlet toward the depth direction for the first region A and a distance of within 3 mm from the end face of the outlet toward the depth direction for the second region B.

### Evaluation 1: Average Crystal Grain Size

As for Example 3, the average crystal grain sizes of the inner wall surface of the through-hole were measured from the outlet, the end face, of the gas nozzle toward the depth direction. Measuring positions were every 0.5 mm from the outlet of the gas nozzle being as zero. The values measured at two points at 0 mm, and 0.5 mm for the first region A, and at three points at 1.0 mm, 1.5 mm, and 2.0 mm for the second region B were averaged. For the measurement, pictures at the positions on the inner wall were shot and taken by a scanning electron microscope and the number of the particles and the average crystal grain size were obtained by image analysis.

### Evaluation 2: Generation of Particles

As for Example 3, a corrosion test for twelve hours with irradiating plasma of CF4 in a chamber of a publicly known ICP etching apparatus was conducted. Then, the number of generated particles was measured with a publicly known aerial particle counter.

In Evaluation 1, for the case of Example 3, the average crystal grain size in the first region A is 3.9 μm and that in the second region B is 4.0 μm, and the ratio of the average crystal grain size in the second region B to that in the first region A is 1.02, which corresponds to the lower limit in the more favorable range of the present invention.

In Evaluation 2, the number of particles generated was 1300 pts. Though this number is inferior to that of Example 1, the number of particles generated was sufficiently small compared to Comparative Example 1, and it can be said that the effect of the present invention has been well obtained.

### Example 4

In Example 4, the effects on the number of generated particles were verified by changing only the jig height, which is the distance from the end face 1A to the surface of the mounting table, among the conditions in Example 1.

The jig used in Example 1 was 30 mm in height, while the jig having a height of 50 mm was used in Example 4. Gas nozzles were manufactured under similar conditions to Example 1 except for the jig height, and Evaluations 1 and 2 were conducted on the nozzles similarly to Example 1.

The gas nozzle manufactured in Example 4, similar to Example 1, has a distance of 0.5 mm from the end face of the outlet toward the depth direction for the first region A and a distance of within 3 mm from the end face of the outlet toward the depth direction for the second region B.

Evaluation 1: Average Crystal Grain Size

As for Example 4, the average crystal grain sizes of the inner wall surface of the through-hole were measured from the outlet, the end face, of the gas nozzle toward the depth direction. Measuring positions were every 0.5 mm from the outlet of the gas nozzle being as zero. The values measured at two points at 0 mm, and 0.5 mm for the first region A, and at three points at 1.0 mm, 1.5 mm, and 2.0 mm for the second region B were averaged. For the measurement, pictures at the positions on the inner wall were shot and taken by a scanning electron microscope and the number of the particles and the average crystal grain size were obtained by image analysis.

### Evaluation 2: Generation of Particles

As for Example 4, a corrosion test for twelve hours with irradiating plasma of CF4 in a chamber of a publicly known ICP etching apparatus was conducted. Then, the number of generated particles was measured with a publicly known aerial particle counter.

In Evaluation 1, for the case of Example 4, the average crystal grain size in the first region A is 3.8 μm and that in the second region B is 4.18 μm, and the ratio of the average crystal grain size in the second region B to that in the first region A is 1.1.

In Evaluation 2, the number of particles generated was 1700 pts. The result of Example 4 is inferior to that of Example 1. However, not to speak of Comparative Example 1, the number of particles generated was sufficiently small compared to Examples 2 and 3, and it can be said that the effect of the present invention has been well obtained.

### REFERENCE SIGNS LIST

1 Gas nozzle
1A End face (with Outlet)
1B End face (with Inlet)
1C Side face
2 Through-hole
2a Inner surface (Inner wall)
2b Outlet
2c Inlet
A First region
B Second region

What is claimed is:

1. A columnar gas nozzle made of sintered ceramics having at least one through-hole through which gas flows,
wherein
the entire surface of an inner surface of the through-hole and an end face on which an outlet of the through-hole is provided are both fired surfaces, the inner surface of the through-hole includes a first region A as an outlet neighboring region and a second region B being located at the depth side from the first region A, and an average crystal grain size at the first region A is smaller than an average crystal grain size at the second region B.

2. The gas nozzle according to claim 1, wherein the distance of the first region A from the end face of the outlet to the depth side is within 0.5 mm, and the second region B is on the further depth side than the first region A, having the distance from the end face of the outlet being within 3 mm, and the average grain size in the second region B is not more than 1.2 times the average grain size in the first region A.
